(19) United States
(12) Patent Application Publication
(10) Pub. No.: US 2016/0298951 A1
(43) Pub. Date: Oct. 13, 2016

(54) METHOD FOR MEASURING A SPHERICAL-ASTIGMATIC OPTICAL SURFACE

(71) Applicant: Carl Zeiss SMT GmbH, Oberkochen (DE)

(72) Inventors: Stefan SCHULTE, Aalen-Waldhausen (DE); Frank SCHILLKE, Aalen (DE)

(21) Appl. No.: 15/187,226

(22) Filed: Jun. 20, 2016

Related U.S. Application Data
(63) Continuation of application No. PCT/EP2014/078678, filed on Dec. 19, 2014.

(30) Foreign Application Priority Data
Dec. 19, 2013 (DE) 10 2013 226 668.5

(51) Int. Cl. G01B 9/02; G01M 11/00; G03F 7/20; G01B 9/021

(52) U.S. Cl. CPC G01B 9/02039; G01B 9/02085; G01B 9/021; G01M 11/005; G03F 7/7015

(57) ABSTRACT

Method for measuring a spherical-astigmatic optical surface (40), includes: a) generating a spherical-astigmatic wavefront as a test wavefront with a wavefront generating apparatus (10); b) interferometrically measuring wavefront aberrations between the wavefront generating apparatus and the surface which is adjusted to the wavefront generating apparatus such that the test wavefront impinges each point on the surface substantially perpendicularly, plural measurements being taken in which the surface is measured at a number of positions, spherized about the two centers of the radii of the astigmatism and/or rotated by 180° about a surface normal to the surface, such that corresponding interferogram phases are determined; and c) determining the wavefront of the wavefront generation device and a shape of the surface using a mathematical reconstruction method. The spherical-astigmatic surface is then corrected using a suitable processing method, a) to c) being repeated until the wavefront aberrations are smaller than a given value.

### CROSS REFERENCE TO RELATED APPLICATIONS

This is a Continuation of International Application PCT/EP2014/078678, which has an international filing date of Dec. 19, 2014, and the disclosure of which is incorporated in its entirety into the present Continuation by reference. The following disclosure is also based on and claims the benefit of and priority under 35 U.S.C. §119(a) to German Patent Application No. DE 10 2013 226 668.5, filed Dec. 19, 2013, which is also incorporated in its entirety into the present Continuation by reference.

### FIELD OF THE INVENTION

The invention relates to a method for measuring a spherical-astigmatic optical surface. The invention furthermore relates to a method for measuring a spherical-astigmatic optical free-form surface. The invention furthermore relates to a test apparatus for a form of an optical free-form surface. The invention furthermore relates to an optical free-form surface.

### BACKGROUND

Astigmatic optical surfaces and free-form surfaces with a large astigmatic component can be tested interferometrically with the aid of a computer-generated hologram (CGH) by virtue of the CGH being designed to generate a wavefront that is perpendicular at each position on the intended surface such that the test object is comprehensively measured in autocollimation.

However, in contrast to rotationally symmetric aspheres, free-form surfaces do not have rotational invariance, and so an interferometric measurement of the surface can generally only take place in precisely one relative position between CGH and test object. This means a large reduction in the measurement accuracy of free-form surfaces in relation to rotationally symmetric aspheres because, in the latter, the non-rotationally symmetric error contributions of interferometer and test object can be cleanly separated as a result of the measurement in theoretically arbitrary many rotational positions. In this case, the achievable figure accuracy lies at approximately 20 pm rms.

By contrast, the figure accuracy in the case of free-form surfaces is currently only at approximately 1 nm since the error contributions of the interferometer, in particular those of the CGH, need to be qualified separately. This is only possible with such an accuracy for the individual parameters that an overall measurement accuracy in the single-digit nanometer range is achieved. Some of the parameters of the CGH are etching depth, duty ratio, trenching, figure, homogeneity of the CGH substrate, etc. Moreover, two rotational positions, namely 0° and 180°, of the interferometer are possible in the case of astigmatic surfaces in relation to free-form surfaces because the astigmatism has a twofold rotational invariance.

Disadvantageously, there currently are no absolute calibration methods for free-form surfaces, as exist, for example, for spherical surfaces (e.g. cat's eye calibration, rotary disc methods, etc.).

Clemens Elster, “Exact two-dimensional wave-front reconstruction from lateral shearing interferograms with large shears”, Applied Optics Vol. 39, No. 29, 10 Oct. 2000 discloses a method for reconstructing or deconvolving errors on an optical surface, wherein shearing of two optical surfaces in relation to one another is measured, whereafter the original wavefront form or the surface form of the test object is reconstructed from the sheared wavefronts by way of integration or deconvolution.

### SUMMARY

It is an object of the present invention to provide an improved method for measuring a spherical-astigmatic optical surface.

In particular, the optical free-form surface in this case should be of the so-called spherical-astigmatic type. Here, this is understood to mean that the form can be represented by a superposition of a spherical surface and a purely astigmatic surface, wherein this superposition is understood to be an addition of the sagittal heights of the astigmatic surface to the sagittal heights of the spherical surface in the normal direction.

In accordance with a first aspect, this object is achieved by a method for measuring a spherical-astigmatic optical surface, including:
a) generating a spherical-astigmatic wavefront as a test wavefront with a wavefront generation device;
b) interferometrically measuring wavefront differences between the wavefront generation device and the spherical-astigmatic surface adapted to the wavefront generation device in such a way that the test wavefront is incident substantially perpendicularly at each point of the spherical-astigmatic surface, wherein a plurality of measurements are carried out, in which the spherical-astigmatic surface is measured at a number of positions, spherized about the two centers of the radii of the astigmatism and/or rotated by 180° about a surface normal of the spherical-astigmatic surface, wherein corresponding interferogram phases are determined;
c) determining the wavefront of the wavefront generation device and a surface form of the spherical-astigmatic surface through a mathematical reconstruction method, according to which the surface of the spherical-astigmatic surface is corrected via a given processing method; and
d) repeating the generating, the measuring and the determining until the wavefront differences are below a defined threshold.

In this way, spherical-astigmatic surfaces can be measured or calibrated absolutely through a so-called shift-shift method. The wavefront forms of the wavefront generation device and of the spherical-astigmatic surface can be determined very exactly by separating the errors of the wavefront generation device and the spherical-astigmatic surface. Preferably, the diameter of the spherical-astigmatic surface is only slightly, in particular approximately 5 to 10%, greater than the wavefront generation device.

In accordance with a second aspect, this object is achieved by a method for measuring a spherical-astigmatic optical free-form surface, including:
a) generating a spherical-astigmatic wavefront as a test wavefront with a wavefront generation device, calibrated with the above-described method with a calibration element;
b) interferometrically measuring regions of the spherical-astigmatic optical free-form surface with the test wavefront, wherein the test wavefront is incident substantially perpendicularly at the free-form surface in each region, wherein the regions of the free-form surface and the test wavefront are displaced in relation to one another and/or spherized and the corresponding interferogram phases are determined; and
c) stitching the free-form surface from the individual regions, wherein the deviations of the test wavefront and the spherical-astigmatic free-from surface are separated from their predetermined values through a mathematical reconstruction method.

In accordance with a third aspect, the object is achieved by a test apparatus for a form of an optical free-form surface, comprising a test optical unit, comprising:
a wavefront generation device for generating a spherical-astigmatic wavefront, adapted to the free-form surface, as a test wavefront, wherein at least portions of the free-form surface are interferometrically testable in each case via the test wavefront and wherein the deviation of the adapted wavefront from the intended form thereof is determined using the calibration method specified as the second aspect of the invention.

In accordance with a fourth aspect, the object is achieved by an optical free-form surface, wherein an astigmatic component of a deviation of the free-form surface from a best-adapted sphere is at least approximately 80%.

In accordance with a fifth aspect, the object is achieved by an optical free-form surface, wherein an astigmatic component of a deviation of the free-form surface from a best-adapted sphere is at least approximately 90%.

Preferred embodiments of the method according to the invention, the test apparatus according to the invention and the free-form surfaces according to the invention are the subject matter of dependent claims.

A preferred embodiment of the method provides for the wavefront of the wavefront generation device to be corrected in step c), wherein steps a) to c) are repeated until the wavefront differences lie below a defined threshold. In this way, a wavefront generation device in the form of a refractive Fizeau element may advantageously be processed until predetermined specifications are met.

A preferred embodiment of the method for measuring a spherical-astigmatic free from surface provides for regions to be embodied as sub-apertures of the free-form surface, wherein scanning of the sub-apertures is carried out using the spherical astigmatic test wavefront. Advantageously, a type of scanning method is carried out thereby, by which a specific class of free-form surfaces can be almost completely calibrated in absolute terms, namely those free-form surfaces whose deviations from a best-adapted sphere are predominantly astigmatic.

Further preferred embodiments of the method provide for a relative movement to be carried out between the spherical-astigmatic surface, or the free-form surface, and the wavefront generation device in accordance with a predefined trajectory in such a way that a substantially comprehensive measurement of the spherical-astigmatic surface, or of the free-form surface, is carried out. Advantageously, an efficient calibration of the wavefront generation device and a measurement of the free-form surface can thus be carried out in this manner in regions in which the deviations of the test wavefront and the deviations of the free-form surface from their respective intended values can be well separated from one another.

A further preferred embodiment of the method for measuring a spherical-astigmatic optical free-form surface provides for partial spherizations to be carried out in directions of axes of the astigmatic surface of the sub-apertures, wherein each partial spherization is carried out about the center of the radius valid in the corresponding axis. In this way, interferograms which are readily evaluable are realizable as a result, said interferograms enabling deviations of the test wavefront and the form of the free-form surface which are readily separable from one another.

Further preferred embodiments of the method provide for the interferometric measurements to be repeatedly carried out, rotated by 180° in each case. In this way, a 180° rotational invariance of the astigmatic basic form of the sub-apertures of the free-form surface is advantageously employed.

With reference to a substantially perpendicular incidence of the test wavefront on the spherical-astigmatic surface or on the free-form surface, reference is made in the context of the present invention to the fact that the incidence comprises both exactly perpendicular incidence and an incidence at an angle which does not exceed a predefined angle value deviating from the normal.

In preferred embodiments of the method according to the invention, provision can be made to this end for the incidence of the test wavefront to occur with, at most, a defined deviation from the normal.

To this end, preferred embodiments of the method provide for the incidence of the test wavefront on the spherical-astigmatic surface or on the free-form surface to be able to occur with a maximum deviation from the normal in the single-digit mrad range.

In preferred embodiments of the methods, provision can be made to this end for the test wavefront to be incident on the spherical-astigmatic surface or the free-form surface with a maximum deviation from the normal of 5 mrad.

In preferred embodiments of the methods, provision can be made to this end for the test wavefront to be incident on the spherical-astigmatic surface or the free-form surface with a maximum deviation from the normal of 2 mrad.

In preferred embodiments of the methods, provision can be made to this end for the test wavefront to be incident on the spherical-astigmatic surface or the free-form surface with a maximum deviation from the normal of 1 mrad. A criterion for all aforementioned embodiments with a defined maximum angle of incidence of the test wavefront is that, in each case, an interferometric measurement of the spherical-astigmatic surface or of the free-form surface may be carried out with the required accuracy.

A preferred embodiment of the test apparatus according to the invention provides for the wavefront generation device to comprise an adaptation element for changing a wavefront into the test wavefront. As a result, the test wavefront can advantageously be adapted in an individual and simple manner to the specific form of the spherical-astigmatic surface or free-form surface to be tested in each case.

A further preferred embodiment of the test apparatus according to the invention provides for a computer-generated hologram to be formed for each spherical-astigmatic surface or free-form surface to be tested, said hologram generating a wavefront which is adapted to a curvature and a mean astigmatism of the spherical-astigmatic surface or the free-form surface. Advantageously, the calibration method listed under the first aspect of the invention may be used to carry out a highly precise surface test for each individual spherical-astigmatic surface or free-form surface.

A further preferred embodiment of the test apparatus according to the invention provides for the wavefront generation device to comprise a plane or spherical reference surface with an additional optical unit for generating an adapted spherical-astigmatic wavefront. As a result, different options for generating the adapted test wavefront are advantageously provided.

A further preferred embodiment of the test apparatus according to the invention provides for the optical free-form surface to be testable in individual sub-apertures. Advantageously, this allows a complete free-form surface to be subdivided into individual regions, in which, apart from a spherical base curvature, substantially astigmatic surface conditions, which can be calibrated easily and precisely in absolute terms, prevail in each case.

Advantageous developments of the optical free-form surfaces according to the invention are distinguished by the specified deviation of the form of the free-form surface from a best-adapted sphere representing an rms value or a PV value of these deviations. As a result, different manifestations of the deviations of the free-form surface from a best-adapted sphere can be described in a uniform manner. Here, the rms (root mean square) value is understood to mean the mean square deviation. Here, the PV value is understood to mean the range between the smallest and largest value.

It is considered to be particularly advantageous that the methods according to the invention and the test apparatus according to the invention render it possible to carry out an absolute calibration of substantially purely spherical-astigmatic surfaces and spherical-astigmatic free-form surfaces. As a result, this opens up the possibility of producing calibrated astigmatic reference surfaces, the form of which lies significantly closer to an intended figure of free-form surfaces than a purely spherical reference; this is justified by virtue of the main component of free-form surfaces often being astigmatic. As a result, this renders it possible to manufacture and test or calibrate optical free-form surfaces very precisely in accordance with predetermined specifications.

This is also rendered possible by virtue of advantageously substantially only tilts being observed between the wavefront, reflected by the test object, and the interferometric reference wavefront, reflected by a reference surface of the test apparatus, in the interferogram generated by the test apparatus in the case of relative movement between test object and test wavefront. Wavefront measured values remaining after adjusting these tilts are obtained exactly and enable precise conclusions to be drawn about deviations of the form of the free-form surface from a best-fit sphere.

As a result, the invention renders possible, in particular, an extension of a measurement spectrum of sub-aperture interferometers. A multiplicity of free-form surfaces in the mid- to high-frequency spatial frequency spectrum can be manufactured and tested with the aid of the adjustable adaptation elements that can be produced. Tests for the purposes of a calibration are likewise encompassed.

Advantageously, a consequence of the invention is the option of a comprehensive calibration of test designs for spherical-astigmatic surfaces in a manner analogous to the rotary-disk calibration of spheres.

The invention is described in detail below with further features and advantages with reference to a number of figures. In this case, all features described or illustrated form by themselves or in any desired combination the subject matter of the invention, independently of their compilation in the patent claims or the dependency reference thereof, and independently of their wording or illustration in the description or in the figures. The figures are intended, in particular, to explain the principles underlying the invention and they are not necessarily depicted true to scale. In the figures, identical or functionally identical elements have identical reference numeral s.

### BRIEF DESCRIPTION OF THE DRAWINGS

FIG. 1 shows a basic illustration of the subdivision into sub-apertures of a free-from surface to be tested;

FIG. 2 shows a basic illustration of separating error contributions from the test object wavefront and reference wavefront;

FIG. 3 shows a basic illustration of identifying an error type of the test object via the method according to the invention;

FIG. 4 shows a test optical unit for testing a spherical-astigmatic surface;

FIG. 5 shows a basic illustration of a test apparatus according to the invention, consisting of an apparatus which generates the spherical-astigmatic test wavefront and a reflecting calibration CGH for absolute calibration of the test wavefront;

FIG. 6A shows a cross-sectional view of a refractive Fizeau element;

FIG. 6B shows a cross-sectional view through a CGH Fizeau element;

FIG. 7 shows a basic sectional view through an EUVL projection lens; and

FIG. 8 shows a basic flowchart of an embodiment of the method according to the invention for measuring an optical free-form surface.

### DETAILED DESCRIPTION

In principle, the invention represents an extension of the rotary-disk method known for spherical surfaces. A spherical surface is invariant in relation to rotations about the surface normal and an arbitrary spherization about the center of the radius thereof.

Analogously thereto, a spherical-astigmatic surface is virtually invariant in relation to any combination of spherizations in the direction of the two “axes” of the astigmatism of the surface, wherein each partial spherization must take place about the center of the radii valid in the corresponding axis.

The aforementioned conditions of a spherical-astigmatic surface can now be employed to displace or spherize a spherical-astigmatic surface, to be tested by interferometry, macroscopically against an astigmatic reference wavefront in arbitrary directions, as a result of which evaluable interferograms with sufficiently small wavefront gradients may be generated and evaluated mathematically. As a result of the mutually shifted wavefronts, it is possible to separate the error contributions of test object wave and reference wave and therefore obtain an absolute calibration of the whole free-form surface. In this way, it is possible to separate interferometer errors from test object errors, as a result of which it is possible to determine what errors may be assigned to the test object and what error may be assigned to the interferometer. Here, astigmatic deformations down to the millimeter range are conceivable.

In the case of e.g. a rotationally symmetric asphere, a spherization of a few 10 μm generally leads to such large wavefront gradients that the interferogram is no longer evaluable. Here, a so-called damping factor of approximately 1000 emerges in the case of asphericities of up to 1 mm in the case of spherical-astigmatic surfaces. The fundamental principle of the spherization-capability of astigmatic surfaces against one another is that the shear of astigmatism against itself results in a tilt which may be largely compensated by tilting the elements against one another, as a result of which the aforementioned damping arises.

The test object wavefront may now be reconstructed by a mathematical separation, carried out via known methods, of the components constant in each interferogram (interferometer error) and the component “being displaced with” the test object.

A further increase in the accuracy can be achieved by way of the 180° rotational invariance of astigmatic surfaces. Therefore, the whole displacement procedure may be repeated in a second rotational position of the surfaces, rotated by 180°, in order thus to obtain improved averaging or an improved consistency of the measurements.

Only virtually spherical surfaces can be calibrated in absolute terms in conventional rotary-disk methods. The absolute calibration of rotationally symmetric aspheres only relates to the non-rotationally symmetric component of the surface or of the test optical unit, the rotationally symmetric component being determined by way of a qualification (i.e. a single determination of error contributions of the test optical unit which is not carried out in the test setup (carried out “externally”)) and not by way of a calibration.

According to the invention, it is possible to carry out a virtually complete absolute calibration of a whole class of aspherical surfaces, namely of those aspherical surfaces which have a spherical-astigmatic character.

To this end, there is a need for a spherical-astigmatic wavefront, which is generated e.g. by a CGH in an interferometer or by a spherical-astigmatic reference surface, wherein the latter should be roughly adapted to the free-form surface to be tested (“test object”). Figure errors of the test object should be so small as a result of the preprocessing process that they are measurable interferometrically against the generated spherical-astigmatic test wavefront.

A spherical-astigmatic wavefront within the meaning of the invention is a wavefront which is generated by adding the sagittal heights of a spherical wave to those of an astigmatic wave.

Provision is made of an apparatus for spherizing the test object macroscopically in any direction about its respective (x- and y-) center of the radius, preferably by at least 10%, more preferably by about 50% of the diameter thereof. Furthermore, the test object should be finely adjustable, i.e. in the μm range or in the gad range, in all degrees of freedom, in particular in terms of tilt or azimuth.

The “shift-shift” calibration described thus can be repeated, as mentioned above, under a 180° rotation of the test object for reference purposes.

The absolute value of the spherization can be varied, but there should be shearing or shifting by at least approximately 5% of the test object diameter in order to achieve a sufficiently good separation between test object wavefront and reference wavefront.

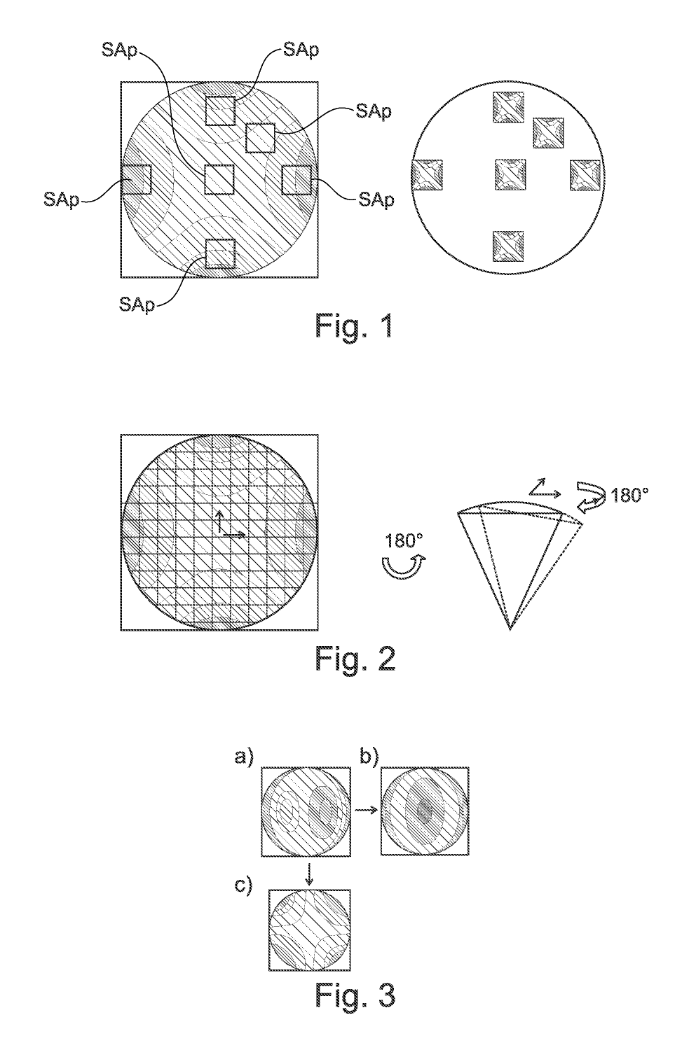

FIG. 1 shows six sub-apertures SAp of a spherical-astigmatic surface, which all have substantially the same deformation. This enables an absolute calibration by virtue of displacing/spherizing two spherical-astigmatic surfaces against one another, determining the interferogram phases and separating the wavefront contributions of the test object wavefront and reference wavefront by way of a mathematical reconstruction method. To this end, a sufficiently large set of phase images from different relative positions is required.

The scales in the sub-apertures SAp show linearly extending grayscale value gradings, which represent the height profile of a test object. Each sub-aperture SAp has a different local tilt applied thereto. When measuring each individual sub-aperture SAp, it is possible to generate virtually the same astigmatic phase profile by tilting the test object or the interferometer, as indicated in the circle on the right. Since the astigmatism is similar in each sub-aperture SAp, said astigmatism can be kept available in the wavefront generation device. The basic curvature of the surface does not appear in the interferogram because, as depicted in FIG. 5, the test beam path extends in adapted divergent manner.

Therefore, the test object or the interferometer is post-tilted for the purposes of minimizing the phase gradient in the interferogram of the respective sub-aperture SAp. The deformation component common to all sub-apertures SAp can now be introduced into the test optical unit (compensation unit) as a constant component such that this always equal phase gradient disappears from the interferograms of the individual sub-apertures SAp, as a result of which the measurement dynamics are significantly increased. Naturally, the illustrated six sub-apertures SAp should merely be seen as exemplary, with test objects with up to approximately 1000 sub-apertures being calibrated in practice.

FIG. 2 is intended to indicate that the sub-apertures SAp may be displaced and/or spherized against one another in the x- and y-direction and may be rotated by 180° in relation to one another in order to separate the error contributions of the test object wavefront and reference wavefront. Thus, firstly, a displacement is carried out, as a result of which, advantageously, only small changes in the ideal wavefront emerge. Additionally, the test object can also be rotated or twisted by 180°, wherein this rotation constitutes an additional option for detecting errors of the test object 40 separately in an improved manner. Advantageously, an additional degree of freedom in the relative movement between the test object and the reference wavefront is thus provided.

The right-hand illustration of FIG. 2 indicates all degrees of freedom (rotation/displacement/spherization) that can be set in the overall system, without the interferogram becoming unusable as a result thereof. In particular, a spherization may be carried out about the center of the radius or the test object may be rotated by 180°, wherein a wavefront is incident substantially perpendicularly on the test object in all of these cases.

In this way, relative measurements may advantageously be carried out and the interferometer wavefront may be separated from the test object wavefront. Ultimately, the interferometer errors “therefore remain stationary” and the test object errors “move along therewith”, wherein these errors may thereupon be separated from one another computationally through a mathematical reconstruction method.

FIG. 2 therefore elucidates that the spherical-astigmatic wavefront and portions of the test object may be shifted in relation to one another and rotated by 180°, without there being a noticeable change in the wavefronts.

FIG. 3 shows, in an exemplary manner, an error, which is detectable or can be calibrated according to the invention, of a test object in the form of a coma. In illustrations b) and c), FIG. 3 shows shear wavefronts (derivatives) of a coma on the test object wavefront depicted in FIG. 3a. Illustration b) shows, in principle, a combination of focus and astigmatism when the coma is sheared or shifted against itself. Here, the shear terms in part result in adjustment components. According to the invention, these can be separated from actually present test object deformations in a unique way by a 180° rotation. Therefore, the figure should indicate what error contributions may be identified by a 180° rotation of the test optical unit. If a coma is present on the test object and the test object is rotated by 180°, the coma, as a result, co-rotates, as is identifiable in illustration c).

In the case of an even aberration, such as a fourth order waviness, sixth order waviness, etc., this would not work because said aberration does not co-rotate on account of the invariance thereof in relation to 180° rotations.

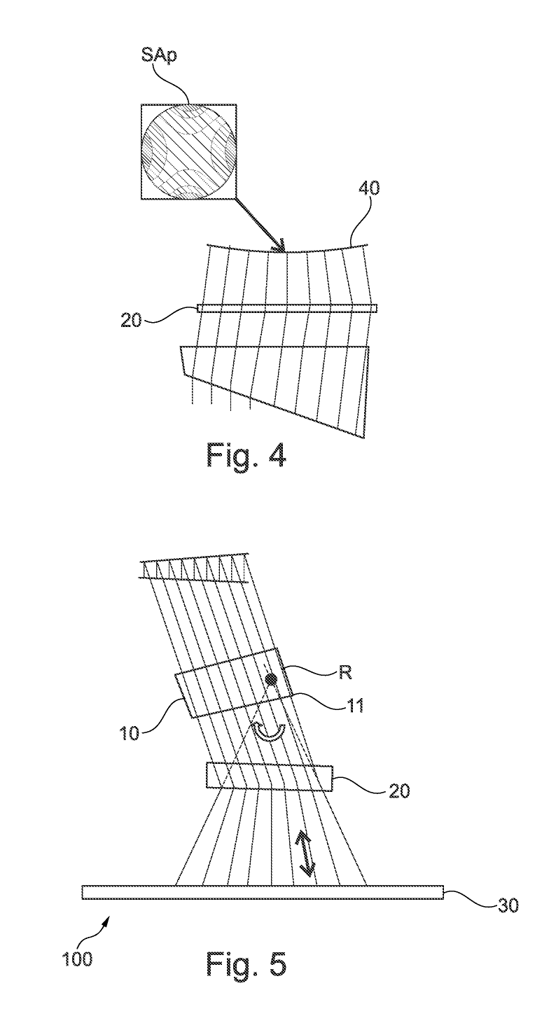

FIG. 4 shows that the absolute calibration of an astigmatic surface may be carried out, for example, on a “spherization mount” by virtue of the test object being measured in various “shift positions”, caused by spherization, in relation to the reference wavefront generated by the CGH. Subsequently, the absolute wavefront of the test object is determined by mathematical reconstruction.

FIG. 4 shows an adaptation element 20, for example in the form of a CGH, which generates the actual reference or test wave. A prism arranged below the adaptation element 20 provides an auxiliary function for a test optical unit by virtue of deflecting a vertical parallel beam from the interferometer in such a way that it is incident obliquely on the adaptation element 20.

A plane wave is incident on the adaptation element 20 coming from below, as result of which the adaptation element 20 generates a spherical-astigmatic wavefront. The black curved line indicates a portion of a test object 40 with a sub-aperture SAp.

The test object 40 is preferably assembled on a holder (not depicted here), on which it may be spherized about the center of the radius thereof in the x- and y-direction and on which it may be rotated by 180°. This is possible because the adaptation element 20 substantially generates a wavefront which corresponds to a surface design of the test object 40. What is very expedient is that a purely spherical-astigmatic wavefront is generated by the adaptation element 20. Thus, in principle, FIG. 4 indicates that a best possible adaptation of the spherical-astigmatic reference wavefront to the free-form surface should be provided for testing a free-form surface.

FIG. 5 shows an embodiment of the test apparatus according to the invention. It is possible to identify a test apparatus 100 with a Fizeau element 10 with a substantially plane reference surface 11. Furthermore, provision is made, in reflection, of an adaptation element 20 (astigmatic CGH) and a calibration element 30 (calibration CGH). For the purposes of an absolute calibration of the astigmatic wavefront of the adaptation element 20, the wavefront of the adaptation element 20 can be spherized as desired against the calibration element 30 using the sensor head (not depicted here) of the calibration machine. The calibration element 30 is designed in such a way that it casts the wave back on itself (in autocollimation), if the latter has its intended form.

During the actual measurement of the surface of the test object 40 (not depicted in FIG. 5), the calibration element 30 should then be replaced by the test object in the form of the free-form surface. It is possible to identify that a center of the radius R of a basic sphere is arranged within the wavefront generation device 10; however, this depends on the wavefront form to be generated, and so said radius could by all means be arranged outside of the wavefront generation device 10 as well. The lowermost portion of the beam path, which is highlighted by a double-headed arrow, represents the test wave.

In practice, provision is made for the test optical unit, comprising the Fizeau element 10 with the reference surface 11 and an adaptation element 20 in the form of a CGH, to be tilted, wherein provision is made of a movable interferometric sensor (not depicted here) relative to the test object 40. Here, the goal each time is to let the wavefront be incident on the test object 40 as perpendicularly as possible or in a substantially perpendicular manner.

In this context, substantially perpendicular means that an interferometric measurement of the spherical-astigmatic surface or of the free-form surface must be possible with sufficient accuracy, wherein this may also be achieved in the case of a not exactly perpendicular incidence of the test wavefront on the spherical-astigmatic surface or free-form surface. It was found that the maximum admissible deviation from the normal may be in the single-digit mrad range, in particular, it may be at most 5 mrad, in particular at most 2 mrad, in particular at most 1 mrad. This requirement applies to each individual one of the sub-apertures SAp to be measured.

Below, a progress of a production process according to the invention for a spherical-astigmatic free-form surface is described in detail, wherein a precondition for the functioning of the production method is that at least 80% of the deviation of the free-form surface from a best-fit sphere is astigmatic.

In order to determine the best-adapted (“best fit”) spherical symmetric surface, it is possible, for example, to minimize the quadratic mean deviation (“rms value”) of the aspherical surface from the spherical symmetric surface to be compared in one predetermined direction. An alternative criterion for determining the best-adapted spherically symmetric surface comprises the peak to valley value (“PV value”), which represents the distance between a highest point and a lowest point on the free-form surface minus the spherically symmetric surface. The most meaningful criterion is to select the sphere in such a way that the maximum of the (absolute value of the) gradient of the difference between the free-form surface and the sphere to be adapted is minimized.

Therefore, within the meaning of the invention, a best-adapted or best-fit sphere is a spherically symmetric form, the deviation of which from the overall form of the free-form surface is minimal.

Preferably, the whole free-form surface is subdivided into individual sub-apertures SAp in such a way that, as a result thereof, a residual gradient within each individual sub-aperture SAp is preferably less than approximately 2 mrad. This residual gradient relates to the relative angles of the surface normals in relation to one another. By way of example, in practice, this may mean that a circle of the sub-aperture SAp has a diameter of approximately 10 mm because it is no longer possible to carry out a sensible measurement in the case of a larger sub-aperture SAp.

Initially, a design process is carried out for the optical free-form surface, for example for an imaging mirror of an EUVL (extreme ultraviolet lithography) lens. In particular, the best-fit radius and astigmatism for the free-form surface is determined for a calibration process.

Thereupon, a spherical-astigmatic Fizeau element is designed, wherein there is an adaptation of the two radii of the astigmatism generated by the Fizeau element in mutually orthogonal sectional planes, taking into account a sought-after operating distance of the Fizeau element in relation to the free-form surface. The aforementioned operating distance is an intended distance between the wavefront generation device 10 and the free-form surface during the measurement to be carried out.

Thereupon, there is a production of the Fizeau element and a fitting counter-surface (calibration surface) with a diameter that is preferably at least approximately 5% larger than the diameter of the Fizeau element, with the aid of a test CGH where necessary.

Subsequently, there is an absolute calibration of the wavefront of the Fizeau element by way of the above-described shift-shift calibration, using a 180° rotation against the aforementioned purely spherical-astigmatic countersurface where necessary, and there is an iterative correction of one or both wavefronts where necessary.

Thereupon, there is an installation of the Fizeau element produced thus into a moveable interferometric sensor and an adjustment of the sensor. Such a sensor, via which portions of the free-form surface may be measured, is disclosed in e.g. US 2012/0229814 A1 or DE 10229816 A1, the disclosures of which are incorporated in their entirety here.

Then, a trajectory for the interferometric sensor relative to the free-form surface to be tested is programmed for the purposes of a comprehensive measurement of sub-apertures SAp. There is an insertion and an adjustment of the free-form surface to be tested in the measurement installation with the interferometric sensor. As a result, an automated travel along the programmed trajectory and a recording of interference images is made possible, and also a calculation and storage of surface topography images of the individual sub-apertures SAp. Preferably, the individual sub-apertures SAp overlap at least in such a way that a union of all sub-apertures SAp yields a superset of the whole free-form surface.

Then, a surface form of the test object in the individual sub-apertures SAp is calculated taking into account the form (radius, astigmatism, residual figure) of the Fizeau element obtained through the above-described absolute calibration.

Then, there is a transformation of the sub-aperture coordinates into a coordinate system of the free-form surface because individual portions of the surface were measured in a local coordinate system. Finally, there is stitching of the free-form surface from the individual sub-apertures SAp to an overall surface.

Now, as a result, a sagittal height value or peak to valley or PV value for the free-form surface on the overall surface is known.

Now, the intended form of the free-form surface, designed at the start, is subtracted from the actual form of the free-form surface, with an evaluation of the deviation of the actual form from the intended form being carried out, the free-form surface subsequently being post-processed in accordance with the determined deviation from the intended form where necessary.

The entire above-described process now is carried out iteratively until form-giving processing steps and measurement loops yield the form of the free-form surface lying within the demanded specification.

Overall, the above-described method renders it possible to produce a free-form surface which is producible and testable in a very accurate manner in the mid- to high frequency range, preferably in the pm range for sagittal height profile, PV value or rms value.

U.S. Pat. No. 7,538,856 B2 and U.S. Pat. No. 7,355,678 B2 have disclosed EUVL projection lenses, the mirrors of which are testable and producible with the method according to the invention. In particular, the method is advantageous for all mirrors shown there because, apart from a basic curvature, all aforementioned mirrors predominantly have an astigmatic embodiment.

In principle, two different types of Fizeau elements are conceivable:

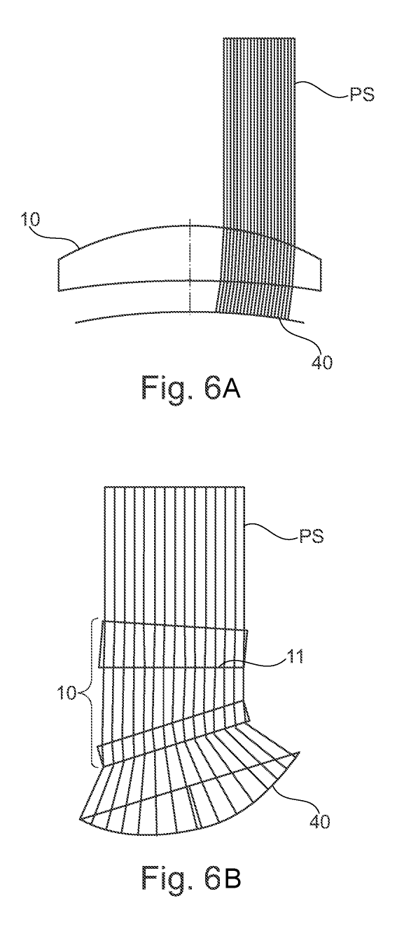

FIG. 6A shows a cross section through a refractive Fizeau element, in which a spherical-astigmatic wave arises as a result of a refraction of a parallel beam PS at the rear side in the glass of the Fizeau element, said wave being perpendicular at each point of the spherical-astigmatic front side of the glass. The wave passing through the glass therefore is likewise a spherical-astigmatic wave and it has the best possible adaptation to a spherical-astigmatic surface or free-form surface to be tested (test object 40) over a defined operating distance.

FIG. 5B shows a cross-sectional view through a CGH Fizeau element with a combination of a Fizeau plate (with the plane reference surface 11 of the interferometer) and the CGH. The CGH generates a spherical-astigmatic wave, which, by way of a defined operating distance, is adapted to the best possible extent to a test object 40 to be tested in the form of a spherical-astigmatic surface or a free-form surface, as a result of which an incidence on the test surface of the test object 40 which is as perpendicular as possible is generated.

Using the above-described shift-shift method, both types of Fizeau elements can be calibrated in absolute terms with the aid of an adapted purely spherical-astigmatic test surface or with a corresponding calibration CGH.

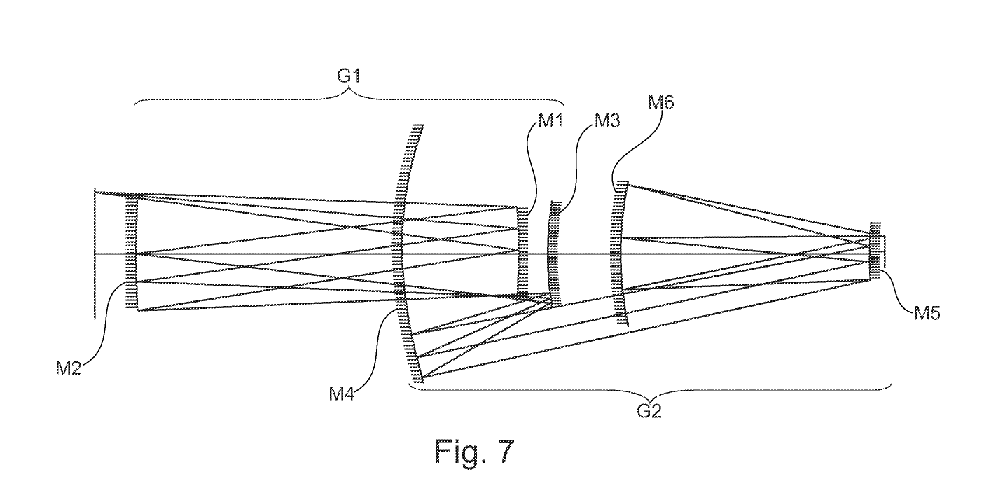

FIG. 7 shows a known, basic view of a lens-element section of an EUVL projection lens comprising a first optical assembly G1 with mirrors M1 and M2, and a second optical assembly G2 with mirrors M3 to M6. Mirrors M5 and M6, in particular, are embodied as free-form surfaces, the astigmatic component of a deviation from a best-adapted sphere of which is at least approximately 80% and, in a particularly preferred embodiment, at least approximately 90%. EUVL projection lenses with eight mirrors, of which at least one mirror is embodied as a free-form surface, are also conceivable (not depicted here).

A plurality of relevant variables should be considered in relation to the approximately 80% to approximately 90% component of the overall deviation of the test object figure from the spherical basic form:
(i) PV or rms of the deviation of the free-form surface from the spherical basic form (=PV(FFF) or rms(FFF))
(ii) PV or rms of the astigmatic component of the free-form surface, for example determinable by way of the fit of Zernike polynomials to the mathematical surface description (=PV(Ast) or rms(Ast))
(iii) PV or rms of the deviation (i) after subtracting the astigmatic component (ii) (=PV(Rest) or rms(Rest)).

The rms values add or subtract approximately quadratically since the deviations from the spherical basic form (firstly, the “astigmatism” and, secondly, the remaining residual error in this case) describable by two-dimensional polynomials are linearly independent, i.e. the following applies:

rms(FFF)=SQRT(rms(Ast)̂2+rms(Rest̂2)

The following follows therefrom:

rms(Ast)=SQRT(rms(FFF)̂2−rms(Rest)̂2)

Here, the following abbreviations are used:
SQRT . . . Square root
PV . . . Peak to valley value
rms . . . Root mean square value
FFF . . . Free-form surface
Rest . . . Residual error

The following definition can be specified for e.g. at least 80% as spherical-astigmatic component of the overall deviation from the spherical basic form:

rms(Rest)/rms(FFF)<0.2(=100%−80%)

Expressed differently, this means that the PV or rms value of the deviation of the free-form surface from the spherical form without the astigmatic component, normalized to the PV or rms value of the overall deviation of the free-form surface from the spherical form should be less than approximately 20%.

All the aforementioned mathematical relationships can also contain the PV value instead of the listed rms value, wherein the relationships only apply approximately, or on average, to the PV value.

With the aid of the method according to the invention, it is possible to produce and test free-form surfaces whose astigmatic component of an overall deviation of the free-form surface from a best-adapted sphere typically lies between a PV value of approximately 0.5 mm and approximately 20 mm. Here, a basic radius of the best-adapted sphere can be embodied between approximately ≧300 mm and approximately infinity (∞). Here, a radius of infinity (∞) corresponds to a plane surface.

In particular, the method according to the invention can be used to produce and test a free-form surface, the local gradient profile of which in any sub-aperture SAp, which is embodied as a circle with a diameter of at least approximately 10 mm, after subtracting a tilt, a focus of the test wave and a purely astigmatic component constant for the whole mirror is at most approximately 2 mrad PV.

In particular, the method according to the invention can be used to produce and test a free-form surface, the deviation of which from the intended form in a spatial wavelength band with a spatial wavelength between approximately 0.5 mm and approximately 50 mm is at most approximately 100 pm to approximately 200 pm, preferably at most approximately 50 pm to 100 pm, more preferably at most approximately 20 pm.

In particular, the method according to the invention can be used to produce and test a free-form surface, the deviation of which from the intended form in the spatial wavelength band with a spatial wavelength between approximately 0.1 mm and approximately 30 mm is at most approximately 100 pm to approximately 200 pm, preferably at most approximately 50 pm to 100 pm, more preferably at most approximately 20 pm.

Additionally, the method according to the invention renders purely spherical-astigmatic surfaces testable with an accuracy of approximately 20 pm after subtracting the focus and astigmatism.

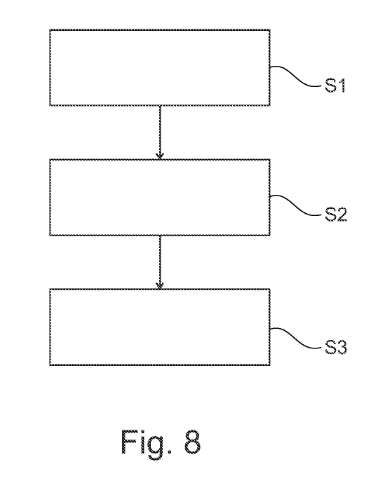

FIG. 8 shows a basic flowchart of an embodiment of the method according to the invention for measuring a spherical-astigmatic surface.

In a first step S1, a spherical-astigmatic wavefront is generated as a test wavefront with a wavefront generation device 10.

In a second step S2, an interferometric measurement of wavefront differences between the wavefront generation device and the spherical-astigmatic surface adapted to the wavefront generation device is carried out in such a way that the test wavefront is incident substantially perpendicularly at each point of the spherical-astigmatic surface, wherein a plurality of the measurements are carried out, in which the spherical-astigmatic surface is measured at a number of positions, spherized about the two centers of the radii of the astigmatism and/or rotated by 180° about the surface normal of the spherical-astigmatic surface, wherein corresponding interferogram phases are determined.

Finally, in a third step S3, the wavefront of the wavefront generation device and the surface form of the spherical-astigmatic surface is determined using a mathematical reconstruction method, according to which the surface of the spherical-astigmatic surface 40 is corrected via a suitable processing method. Steps S1 to S3 are repeated until the wavefront differences lie below a defined threshold.

In conclusion, the present invention proposes a method for measuring a spherical-astigmatic optical surface, a method for measuring a spherical-astigmatic optical free-form surface and a test apparatus for a form of an optical free-form surface.

Advantageously, the invention renders possible highly precise manufacturing and testing of the figure of spherical-astigmatic surfaces, in particular free-form surfaces with a high spherical-astigmatic component. Advantageously, the free-form surface is measurable with a high resolution on account of the principle of scanning in portions, wherein a high spatial resolution and, in specific frequency bands, a substantially higher accuracy is achievable than with conventional methods. Advantageously, free-form surfaces with accuracy in the pm range can be produced and measured as described here.

Preferably, provision is made of forming a dedicated calibration CGH and/or a dedicated spherical-astigmatic calibration surface for each test object. In practice, a plurality of optical components for lenses with free-form surfaces are advantageously exactly testable in this manner.

The invention exploits the fact that most free-form surfaces have only a “basic astigmatism” and only weakly developed further deviation profile components in addition to the basic curvature thereof, wherein a test optical unit consisting of generation device is formed for each individual one of these surfaces, wherein a reference curvature and a reference astigmatism of the testing wavefront is adapted to the basic form of the test object.

The person skilled in the art will herewith be enabled to suitably modify the described features or combine them with one another, without departing from the essence of the invention.

What is claimed is:

1. A method for measuring a spherical-astigmatic optical surface, comprising:
a) generating a spherical-astigmatic wavefront as a test wavefront with a wavefront generation device;
b) interferometrically measuring wavefront differences between the wavefront generation device and the spherical-astigmatic surface adapted to the wavefront generation device such that the test wavefront is incident substantially perpendicularly at each point of the spherical-astigmatic surface, wherein said measuring comprises carrying out a plurality of measurements, in which the spherical-astigmatic surface is measured at a number of positions, spherized about two centers of the radii of the astigmatism and/or rotated by 180° about a surface normal of the spherical-astigmatic surface, and determining corresponding interferogram phases;
c) determining the wavefront of the wavefront generation device and a surface form of the spherical-astigmatic surface through a mathematical reconstruction method, according to which the surface of the spherical-astigmatic surface is corrected via a given processing method, and
d) repeating said generating, said measuring and said determining until the wavefront differences are below a defined threshold.

2. The method as claimed in claim 1, wherein the wavefront of the wavefront generation device is corrected during said determining, and wherein said generating, said measuring and said determining are repeated until the wavefront differences are below the defined threshold.

3. The method as claimed in claim 1, wherein the spherical-astigmatic surface is embodied as a calibration element for the wavefront generation device.

4. A method for measuring a spherical-astigmatic optical free-form surface, comprising:
a) generating a spherical-astigmatic wavefront as a test wavefront with a wavefront generation device calibrated according to the measuring method as claimed in claim 1 utilizing a calibration element as the spherical-astigmatic surface;
b) interferometrically measuring regions of the spherical-astigmatic surface, embodied as an optical free-form surface, with the test wavefront, wherein the test wavefront is incident substantially perpendicularly on the free-form surface at each of the regions, wherein the regions of the free-form surface and the test wavefront are displaced in relation to one another and/or spherized, and determining the corresponding interferogram phases; and
c) stitching the free-form surface from the regions, wherein deviations of the test wavefront and the spherical-astigmatic free-from surface differ from respective predetermined values in accordance with a mathematical reconstruction method.

5. The method as claimed in claim 4, wherein the regions are embodied as sub-apertures of the free-form surface, wherein scanning of the sub-apertures is carried out using the spherical astigmatic test wavefront.

6. The method as claimed in claim 5, wherein a relative movement is carried out between the free-form surface and the wavefront generation device in accordance with a predefined trajectory, so as to perform a substantially comprehensive measurement of the free-form surface.

7. The method as claimed in claim 5, wherein partial spherizations are carried out in directions of axes of the astigmatic surface of the sub-apertures, wherein each partial spherization is carried out about a center of a radius valid in the corresponding axis.

8. The method as claimed in claim 5, wherein the interferometric measurements are carried out repeatedly, rotated respectively by 180°.

9. The method as claimed in claim 5, wherein the test wavefront is incident on the free-form surface with a maximum deviation less than 10% from normal incidence.

10. The method as claimed in claim 4, wherein the wavefront generation device and the free-form surface are manufactured in an iterative manufacturing process.

11. A test apparatus for testing a surface form of an optical free-form surface, comprising a test optical unit, comprising:
a wavefront generation device configured to generate a spherical-astigmatic wavefront, adapted to the free-form surface, as the test wavefront, wherein at least portions of the free-form surface are interferometrically respectively tested with the test wavefront and wherein the deviation of the adapted wavefront from the intended form thereof is determined with the method as claimed in claim 4.

12. The test apparatus as claimed in claim 11, wherein the wavefront generation device comprises an adaptation element for changing a wavefront into the test wavefront.

13. The test apparatus as claimed in claim 11, configured to generate a computer-generated hologram for each free-form surface to be tested, said hologram generating a wavefront which is adapted to a curvature and a mean astigmatism of the free-form surface.

14. The test apparatus as claimed in claim 12, wherein the wavefront generation device comprises a plane or spherical reference surface with an additional optical unit configured to generate an adapted spherical-astigmatic wavefront.

15. An optical element comprising a free-form surface, wherein an astigmatic component of a deviation of the free-form surface from a best-adapted sphere is at least 80%.

16. The optical element as claimed in claim 15, wherein the deviation represents a root-mean-square (rms) value of the deviation.

17. The optical element as claimed in claim 16, wherein the deviation represents a peak-to-valley (PV) value of the deviation.

18. The optical element as claimed in claim 17, wherein an astigmatic component of an overall deviation of the free-form surface from a best-adapted sphere is between a PV value of approximately 0.5 mm and approximately 20 mm, wherein a basic radius of the best-adapted sphere is between approximately ≧300 mm and approximately infinity.

19. An imaging optical system, comprising at least one extreme ultraviolet lithography projection lens comprising a plurality of mirrors, at least one of which comprises at least one optical free-form surface as claimed in claim 15.
